(19) United States
(12) Patent Application Publication
(10) Pub. No.: US 2009/0233456 A1
(43) Pub. Date: Sep. 17, 2009

(54) IRRADIATION OPTICAL SYSTEM, IRRADIATION APPARATUS AND FABRICATION METHOD FOR SEMICONDUCTOR DEVICE

(75) Inventor: Koichi Tsukihara, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: Sony Corporation, Tokyo (JP)

(21) Appl. No.: 12/392,162

(22) Filed: Feb. 25, 2009

(30) Foreign Application Priority Data
Mar. 17, 2008 (JP) 2008-066972

(51) Int. Cl. H01L 21/26; G02B 5/30

(52) U.S. Cl. 438/795; 359/483; 257/E21.328

(57) ABSTRACT

An irradiation optical system includes: a first projection optical system for mixing a plurality of luminous fluxes outputted from a laser light source having a plurality of linearly arrayed light emitting points with each other and dividing the mixed luminous fluxes into a plurality of luminous fluxes and then projecting, to a slit member having a plurality of slits parallel to each other, the plural luminous fluxes as a line beam extending across the plural slits; and a second projection optical system for projecting an image of the plural slits of the slit member to an irradiation target.

### CROSS REFERENCES TO RELATED APPLICATIONS

The present invention contains subject matter related to Japanese Patent Application JP 2008-066972 filed in the Japan Patent Office on Mar. 17, 2008, the entire contents of which being incorporated herein by reference.

### BACKGROUND OF THE INVENTION

1. Field of the Invention

This invention relates to an irradiation optical system, an irradiation apparatus and a fabrication method for a semiconductor device and is suitable for use with, for example, an irradiation optical system wherein a high-output broad area type multi-emitter semiconductor laser is used as a light source, an irradiation apparatus which uses the irradiation optical system and a fabrication method for a semiconductor device which uses the irradiation apparatus.

2. Description of the Related Art

In related art, such an illumination apparatus as shown in FIG. 9 is known as an illumination apparatus for illuminating a linear illumination area with a laser beam (refer to Japanese Patent Laid-Open No. 2002-72132, hereinafter referred to as Patent Document 1). It is to be noted that FIG. 9 is similar to the FIG. 1 of Patent Document 1. Referring to FIG. 9, luminous fluxes or laser beams 102 outputted from a plurality of linearly arrayed emitters or light emitting points 101a of a bar laser 101 are collimated in a perpendicular direction and a parallel direction to the array direction of the emitters 101a and simultaneously mixed with each other by collimator lenses 102 and 104. Resulting luminous fluxes are inputted to a cylindrical lens array 105 formed from a pair of cylindrical lenses 105a and 105b and are divided into a plurality of luminous fluxes by the cylindrical lenses 105a and 105b. Then, the luminous fluxes are transmitted through cylindrical lenses 106 and 107 to form a line beam, which is irradiated on a linear illumination area on the surface of a spatial light modulator 108.

On the other hand, for example, where a TFT (thin film transistor) substrate which is used as an element substrate of a liquid crystal display, an organic electroluminescence (EL) display or the like is to be fabricated, a method is available wherein an amorphous silicon film is formed on the overall face of a glass substrate or the like and a laser beam is irradiated on a stripe-shaped region including a TFT formation region in pixels of the amorphous silicon film to form a polycrystalline silicon film by laser annealing. In this instance, it is necessary not to irradiate the laser beam on any other portion of the amorphous silicon film than the stripe-shaped region. This is because each pixel includes a portion on which it is desirable not to irradiate a laser beam such as a wiring line portion.

Another illumination apparatus is known and disclosed, for example, in Japanese Patent Laid-Open No. 2007-47335 (hereinafter referred to as Patent Document 2). The illumination apparatus includes a light emitting device array having a non-uniform light distribution characteristic, a plurality of coupling lenses arranged individually corresponding to light emitting devices of the light emitting device array, a first lens array, a second lens array and an illumination target face. The illumination apparatus further includes an optical device disposed between the coupling lens and the first lens array or in the proximity of the coupling lens and the first lens array for reducing a non-uniform light amount distribution on the illumination target face arising from the light distribution characteristic of the light emitting devices.

Further, a confocal microscope has been proposed and is disclosed in PCT Patent Publication No. WO04/036284 (hereinafter referred to as Patent Document 3). The confocal microscope includes an incident optical system for inputting polarized light from an illumination light source to an observation target through a matrix type liquid crystal element, above which a microlens array is disposed, and an objective lens, a detection optical system for detecting reflection light or fluorescence from the observation target, and a liquid crystal controlling section for controlling the liquid crystal element. Light beams of the microlenses transmitted through the microlens array are transmitted through the individual pixels of the liquid crystal element and are focused on the observation target by the objective lens. Further, the polarization directions of the light transmitted through the pixels of the liquid crystal element are controlled by the liquid crystal controlling section so that the polarization directions of the light to be transmitted through the pixels may be orthogonal to each other.

### SUMMARY OF THE INVENTION

However, according to investigations of the inventor of the present invention, if the illumination apparatus shown in FIG. 9 is used where a laser beam is irradiated only on a stripe-shaped region including a TFT formation region in pixels as described above, then since the dispersion of the irradiation intensity is great among different regions, there is a problem that it is difficult to uniformly irradiate a laser beam on the regions and consequently a characteristic of the TFT becomes non-uniform among the pixels.

In particular, in order to irradiate a laser beam on a specific region of an irradiation target, a slit member having a plurality of slits extending in parallel to each other in a direction perpendicular to the array direction of the emitters 101a of the bar laser 101 is used in place of the spatial light modulator 108 shown in FIG. 9. Then, the laser beams are irradiated on a linear illumination area of the slit member, which extends transversely to the slits, and a luminous flux transmitted through the slit member, that is, a line beam, is irradiated on the surface of the irradiation target through a relay lens. While the intensity distribution of the line beam on the surface of the irradiation target in this case exhibits such a comb shape as shown in FIG. 10, actually the uniform irradiation performance can be obtained by up to approximately 5% from the dispersion in luminance of the emitters 101a of the bar laser 101, the dividing number of the cylindrical lenses 105a and 105b, insufficient alignment of the optical system, an influence of aberrations of optical system such as curvature of field, an influence of interference fringes by coherence or speckles and so forth. For example, it is difficult to reduce the dispersion of the average intensity of the line beam among A, B, C portions shown in FIG. 10 to approximately 5% or less.

If the dispersion of the average intensity of the line beam is approximately 5% or more, then it is difficult to apply the line beam irradiation to fabrication of a TFT substrate. In particular, the influence by irradiation of a non-uniform line beam wherein the dispersion of the average intensity is approximately 5% remarkably appears particularly with laser annealing by which an amorphous silicon film is changed into a polycrystalline silicon film in fabrication of a TFT substrate for an organic EL display. For example, if the intensity of the line beam is non-uniform in an X axis direction as shown in FIG. 10, then a difference in characteristic of a polycrystalline silicon film appears among the pixels, and accordingly, a difference in characteristic among polycrystalline silicon TFTs appears. Then, the difference appears as luminance ununiformity of the organic EL panel. In order to suppress the luminance ununiformity, generally the permissible ununiformity of the irradiation intensity among the pixels is only approximately several percent.

Therefore, it is desirable to provide an irradiation optical system which can suppress, where a beam is irradiated on a specific region of an irradiation target, the dispersion of the irradiation intensity among different regions sufficiently small to carry out line beam irradiation, an irradiation apparatus which uses the irradiation optical system and a fabrication method for a semiconductor device which uses the irradiation apparatus.

According to an embodiment of the present invention, there is provided an irradiation optical system including a first projection optical system for mixing a plurality of luminous fluxes outputted from a laser light source having a plurality of linearly arrayed light emitting points with each other and dividing the mixed luminous fluxes into a plurality of luminous fluxes and then projecting, to a slit member having a plurality of slits parallel to each other, the plural luminous fluxes as a line beam extending across the plural slits, and a second projection optical system for projecting an image of the plural slits of the slit member to an irradiation target. The second projection optical system includes a polarization controlling element array having a plurality of polarization controlling elements equal to the number of the plural slits, for receiving the plural luminous fluxes transmitted through the plural slits of the slit member and controlling polarization of the received plural luminous fluxes, and an intensity adjustment element for receiving the plural luminous fluxes transmitted through the polarization controlling element array and adjusting the intensity of the plural luminous fluxes.

In the irradiation optical system, the oscillation wavelength of the laser light source having the plural light emitting points arrayed linearly is selected suitably in response to the contents of a process to be applied to the irradiation target and so forth. For example, in order to carry out laser annealing of an amorphous silicon film, the oscillation frequency of the laser light source is selected to a wavelength in the near infrared region or the ultraviolet region. The laser light source is not limited particularly but is selected as occasion demands. However, typically a multi-emitter semiconductor laser, for example, a multi-emitter semiconductor laser of the broad area type, is used.

Typically, the distance between the plural polarization controlling elements of the polarization controlling element array is selected to be equal to that between the plural slits of the slit member. However, the distance is not limited to this. The polarization controlling element array may be disposed adjacent to the slit member in an irradiation target side or may be disposed at a position optically conjugate with the slit member and the irradiation target. In the latter case, the second projection optical system projects the image of the plural slits of the slit member to the polarization controlling element array and projects an image obtained by the polarization controlling element array to the irradiation target.

Each of the polarization controlling elements is formed from a half-wave plate mounted for rotation around a center axis thereof parallel to the inputting direction of the luminous fluxes to the polarization controlling elements or from a Soleil compensator. However, the polarization controlling elements are not limited to them. While a related Soleil compensator may be used as the Soleil compensator, the Soleil compensator may include a birefringent substrate, a first wedge substrate disposed in a connecting or adjacent relationship with the birefringent substrate and extending orthogonally to an optical axis of the birefringent substrate, and a second wedge substrate having a wedge angle and an optical axis same as those of the first wedge substrate and disposed so as to face to the first wedge substrate, one of the first and second wedge substrates being capable of being adjusted in a wedge direction by sliding. The fixed side birefringent substrates and the first wedge substrates of the polarization controlling elements may be integrated into a unitary birefringent substrate and a unitary wedge substrate, respectively.

After the plural luminous fluxes outputted from the laser light source are mixed with each other, they are transmitted through the polarization controlling elements to rotate the polarization plane thereof as occasion demands. For the polarization controlling elements, for example, a half-wave plate is used.

The intensity adjustment element is formed typically from an optical isolator. However, some other element may be used only if it can adjust the intensity of the luminous fluxes inputted thereto depending upon the polarization state of the luminous fluxes.

According to another embodiment of the present invention, there is provided an irradiation apparatus including an irradiation optical system including a first projection optical system for mixing a plurality of luminous fluxes outputted from a laser light source having a plurality of linearly arrayed light emitting points with each other and dividing the mixed luminous fluxes into a plurality of luminous fluxes and then projecting, to a slit member having a plurality of slits parallel to each other, the plural luminous fluxes as a line beam extending across the plural slits, and a second projection optical system for projecting an image of the plural slits of the slit member to an irradiation target. The second projection optical system includes a polarization controlling element array having a plurality of polarization controlling elements equal to the number of the plural slits, for receiving the plural luminous fluxes transmitted through the plural slits of the slit member and controlling polarization of the received plural luminous fluxes, and an intensity adjustment element for receiving the plural luminous fluxes transmitted through the polarization controlling element array and adjusting the intensity of the plural luminous fluxes.

The irradiation apparatus includes, in addition to the irradiation optical system, a stage for carrying the irradiation target, a control apparatus for the stage and so forth.

According to a further embodiment of the present invention, there is provided a fabrication method for a semiconductor device, including a step of irradiating, on a semiconductor substrate or a semiconductor film, a line beam obtained using an irradiation apparatus which includes an irradiation optical system which in turn includes a first projection optical system for mixing a plurality of luminous fluxes outputted from a laser light source having a plurality of linearly arrayed light emitting points with each other and dividing the mixed luminous fluxes into a plurality of luminous fluxes and then projecting, to a slit member having a plurality of slits parallel to each other, the plural luminous fluxes as a line beam extending across the plural slits, and a second projection optical system for projecting an image of the plural slits of the slit member to an irradiation target. The second projection optical system includes a polarization controlling element array having a plurality of polarization controlling elements equal to the number of the plural slits, for receiving the plural luminous fluxes transmitted through the plural slits of the slit member and controlling polarization of the received plural luminous fluxes, and an intensity adjustment element for receiving the plural luminous fluxes transmitted through the polarization controlling element array and adjusting the intensity of the plural luminous fluxes.

The fabrication method for a semiconductor device can be applied to fabrication of various semiconductor devices by applying various processes such as, for example, laser annealing, to a semiconductor substrate such as, for example, a silicon substrate or a semiconductor thin film such as a silicon thin film utilizing light irradiation. In particular, the fabrication method can be applied to fabrication of a TFT substrate, for example, for a liquid crystal display or an organic EL display.

In the irradiation optical system, irradiation apparatus and fabrication method for a semiconductor device, even if a line beam emitted from the first projection optical system and having a comb-shaped intensity distribution has a non-uniform intensity caused by a dispersion in luminance among the light emitting points of the laser light source, insufficient alignment of the optical system, an influence of aberration of the optical system such as curvature of field, an influence of interference fringes by coherence and speckles and so forth, the polarization controlling elements of the polarization controlling element array can be adjusted individually in response to the intensity distribution to control the polarization to individually adjust the intensities of the luminous fluxes through the intensity adjustment element. Consequently, the intensity of the line beam emitted from the second projection optical system so as to be irradiated upon the irradiation target can be uniformized.

With the irradiation optical system, irradiation apparatus and fabrication method for a semiconductor device, a line beam having non-uniformity of the intensity smaller than approximately 5%, such as, for example, approximately several percent and having a comb-shaped intensity distribution can be obtained readily. By irradiating the line beam upon a plurality of particular regions of the irradiation target, the dispersion in irradiation intensity among the regions can be suppressed to a sufficiently low level.

### BRIEF DESCRIPTION OF THE DRAWINGS

FIGS. 1A to 2B are schematic diagrammatic views showing an irradiation optical system according to a first embodiment of the present invention and an example of the intensity distribution of a line beam irradiated on an irradiation target;

FIG. 3 is a schematic diagrammatic view showing a polarization controlling element array used in the irradiation optical system according to the first embodiment of the present invention;

FIGS. 4 and 5 are schematic diagrammatic views showing polarization controlling element arrays used in irradiation optical systems according to second and third embodiments of the present invention, respectively;

FIG. 6 is a schematic view showing an irradiation optical system according to a fourth embodiment of the present invention;

FIG. 7A is a schematic perspective view showing an irradiation apparatus according to a fifth embodiment of the present invention and FIG. 7B is an enlarged view of a line beam irradiation section of the irradiation apparatus;

FIG. 8 is a sectional view illustrating an example wherein the irradiation apparatus according to the fifth embodiment of the present invention is applied to fabrication of a TFT substrate;

FIG. 9 is a schematic diagrammatic view showing a related illumination apparatus; and

FIG. 10 is a schematic view showing an example of the intensity distribution of a line beam obtained by the related illumination apparatus shown in FIG. 9.

### DETAILED DESCRIPTION OF THE PREFERRED EMBODIMENTS

In the following, preferred embodiments of the present invention are described with reference to the drawings.

First, an irradiation optical system according to a first embodiment of the present invention is described.

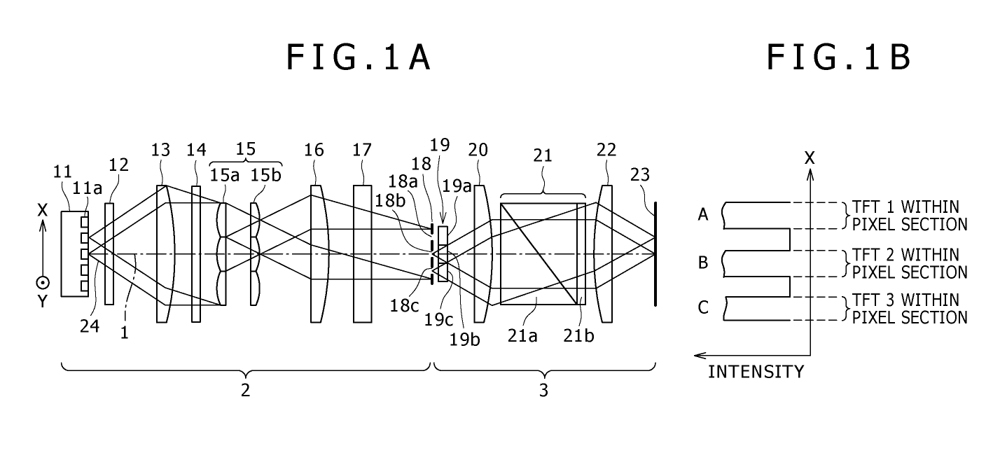

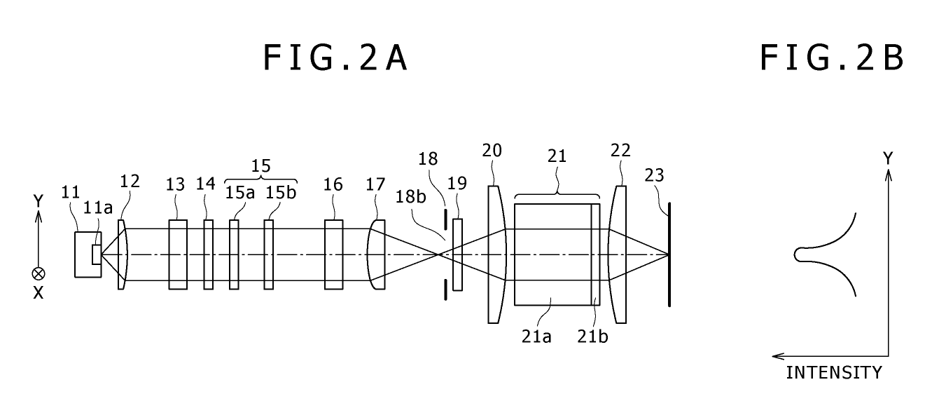

FIGS. 1A to 2B show a configuration of the irradiation optical system. One direction in a plane perpendicular to an optical axis 1 of the irradiation optical system is defined as the X axis and another direction perpendicular to the direction is defined as the Y axis. FIG. 1A is a view of the irradiation optical system as viewed in the Y axis direction and FIG. 2A is a view of the irradiation optical system as viewed in the X axis direction.

As shown in FIGS. 1A and 2A, the irradiation optical system includes a first projection optical system 2 and a second projection optical system 3 on the optical axis 1 thereof.

The first projection optical system 2 includes a one-dimensional multi-emitter semiconductor laser 11, collimator lenses 12 and 13, a half-wave plate 14, a cylindrical lens array 15 formed from a pair of cylindrical lenses 15a and 15b, a condenser lens 16, a condensing lens 17 and a slit member 18, which are formed on the optical axis 1.

The second projection optical system 3 includes a polarization controlling element array 19, a projection lens 20, an optical isolator 21 and another projection lens 22 which are disposed on the optical axis 1. A line beam outputted from the second projection optical system 3 is irradiated on an irradiation target 23.

The multi-emitter semiconductor laser 11 includes a plurality of emitters or light emitting points 11a linearly arrayed in the X axis direction. If the multi-emitter semiconductor laser 11 is oscillated, then a luminous flux or laser beam 24 having a main axis parallel to the optical axis 1 is outputted from each of the emitters 11a. While the number of the emitters 11a is not limited specifically but is selected as occasion demands, as an example, the number of the emitters 11a is five in FIG. 1A. Further, the distance between the emitters 11a is not limited specifically but is selected as occasion demands.

The luminous fluxes 24 outputted from the multi-emitter semiconductor laser 11 are inputted to the collimator lens 12 and collimated in the Y axis direction by the collimator lens 12 (refer to FIG. 2A). The luminous fluxes collimated in the Y axis direction are inputted to the collimator lens 13 and collimated in the X axis direction by the collimator lens 13, and the collimated luminous fluxes are mixed with each other (refer to FIG. 1A). The luminous fluxes collimated in the X and Y axis directions and mixed with each other are inputted to the half-wave plate 14, by which the polarization plane thereof is rotated to a direction of 45 degrees with respect to the X and Y axes.

The luminous fluxes transmitted through the half-wave plate 14 are successively transmitted through the cylindrical lenses 15a and 15b individually having a plurality of cylindrical lenses arrayed in the X axis direction and are divided into a plurality of luminous fluxes in the X axis direction. The luminous fluxes divided in the X axis direction in this manner are converged in the X axis direction by the condenser lens 16 (refer to FIG. 1A). Further, the converged luminous fluxes are condensed at the slit member 18 by the condensing lens 17 as viewed from the Y axis direction to form a line beam spread to the overall slit member 18 in a plane including the optical axis 1 and the X axis (refer to FIG. 2A). The slit member 18 has a plurality of slits arrayed in the X direction and extending in parallel to each other in the Y axis direction. While the number of the slits of the slit member 18 is not limited specifically but is selected as occasion demands, three slits 18a, 18b and 18c are shown in FIG. 1A.

Consequently, the luminous fluxes 24 outputted from the multi-emitter semiconductor laser 11 are projected as the line beam extending across the plural slits, that is, the slits 18a, 18b and 18c in the example shown in FIG. 1A, in the slit member 18. In other words, an image of the luminous fluxes 24 is formed on the slit member 18.

The polarization controlling element array 19 is disposed just behind the slit member 18. The polarization controlling element array 19 is configured from a plurality of polarization controlling elements arrayed linearly in the X axis direction and disposed just behind the slits of the slit member 18. The number of the polarization controlling elements is equal to that of the slits of the slit member 18, and the polarization controlling elements are disposed in a spaced relationship from each other same as that of the slits. Three polarization controlling elements 19a, 19b and 19c are shown in FIG. 1A corresponding to the three slits 18a, 18b and 18c, respectively. It is desirable to set the distance between the polarization controlling element array 19 and the slit member 18 sufficiently short so that the luminous fluxes transmitted through the slits of the slit member 18 are inputted only to the polarization controlling elements corresponding to the transmitting slits but not inputted to the other polarization controlling elements.

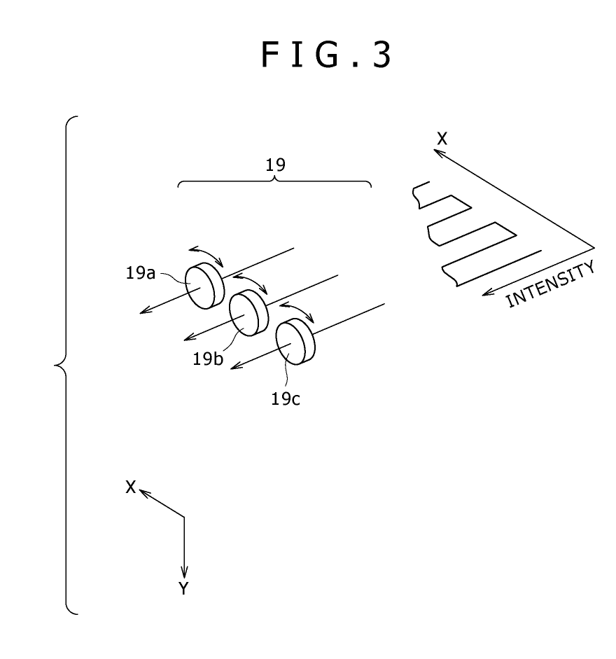

Details of the polarization controlling element array 19 having the polarization controlling elements 19a, 19b and 19c are shown in FIG. 3. Referring to FIG. 3, each of the polarization controlling elements 19a to 19c is formed from a half-wave plate having a disk shape parallel to the X-Y plane. The center axis of each of the polarization controlling element 19a to 19c extends in parallel to the optical axis 1. The polarization controlling elements 19a to 19c are configured for individual rotation around the center axis thereof by a rotation mechanism not shown. A publicly known rotation mechanism can be used for the rotation mechanism and is selected as occasion demands. By individually adjusting the rotational angles of the polarization controlling elements 19a to 19c individually formed from a half-wave plate, the angles of polarization planes of the luminous fluxes inputted to the polarization controlling elements 19a to 19c can be individually adjusted.

It is to be noted that, where adjustment of the angle of the polarization plane can be sufficiently carried out by adjustment of the rotational angles of the polarization controlling elements 19a to 19c, the half-wave plate 14 may be omitted.

Referring back to FIGS. 1A to 2B, the luminous fluxes projected as the line beam on the slit member 18 and transmitted through the slits are inputted to the polarization controlling elements of the polarization controlling element array 19 such that polarization thereof is controlled. The luminous fluxes having the controlled polarization and outputted from the polarization controlling element array 19 in this manner are converged by the projection lens 20, and then the resulting luminous fluxes are inputted to the optical isolator 21. The optical isolator 21 is composed of a polarization beam splitter 21a and a quarter wave plate 21b provided on the output face of the polarization beam splitter 21a. When the luminous fluxes inputted to the optical isolator 21 are transmitted through the polarization beam splitter 21a, the intensity thereof is varied in response to the polarization state thereof. More particularly, the intensity of the luminous fluxes transmitted through the polarization beam splitter 21a varies in response to the direction of the polarization plane of the incident luminous fluxes with respect to the polarization beam splitter 21a. The quarter wave plate 21b provided on the output face of the polarization beam splitter 21a prevents returning light.

The luminous fluxes outputted from the optical isolator 21 are irradiated on the irradiation target 23 by the projection lens 22. Consequently, an image on the slits of the slit member 18 on which the luminous fluxes are projected as the line beam is projected to the irradiation target 23. In other words, the image on the slits of the slit member 18 is formed on the irradiation target 23. Here, the slit member 18 and the irradiation target 23 are optically conjugate with each other. An example of the intensity distribution of the line beam irradiated on the irradiation target 23 in the X and Y axis directions is shown in FIGS. 1B and 2B, respectively.

Control of polarization by the polarization controlling element array 19 is performed in the following manner.

Here, it is assumed that the luminous fluxes are projected as the line beam to the slit member 18 and the intensity distribution of the luminous fluxes outputted from the slits in the X axis direction is in such a state as shown in FIG. 3. As seen in FIG. 3, the intensity of the luminous fluxes inputted to the polarization controlling elements 19a to 19c increases in order from the element 19a to the element 19c. The dispersion of average intensity among the luminous fluxes is, for example, approximately 5% or more. In this case, for example, the rotational angle of the polarization controlling element 19a is adjusted so that the luminous flux inputted to the polarization controlling element 19c is outputted from the optical isolator 21 in a state wherein the intensity thereof is maintained as it is. On the other hand, the rotational angles of the polarization controlling elements 19b and 19c are adjusted so that the intensity of the luminous fluxes inputted thereto is reduced when they are transmitted through the optical isolator 21 so as to become equal to the intensity of the luminous flux transmitted through the polarization controlling element 19a. Consequently, the intensities of the luminous fluxes outputted from the optical isolator 21 are equal to each other. As a result, the intensity distribution of the line beam irradiated on the irradiation target 23 is equalized significantly as seen in FIG. 1B in comparison with that in the alternative case illustrated in FIG. 3. For example, the dispersion of the average intensity among the intensities A, B and C shown in FIG. 1B can be reduced to approximately 3%.

As described above, with the irradiation optical system according to the first embodiment, by controlling the polarization controlling elements of the polarization controlling element array 19 to the optimum state in advance in response to the intensity of the luminous fluxes transmitted through the slits of the slit member 18 to which the luminous fluxes are projected as the line beam, a line beam of a large width which has the comb-shaped intensity distribution and wherein, for example, the dispersion of the average intensity is as small as approximately 3% can be formed easily. Further, by irradiating the line beam on the irradiation target 23, the line beam can be irradiated on a plurality of specific regions while suppressing the dispersion of the irradiation intensity among the regions to a sufficiently low level. Further, in order not to individually correct various errors appearing on the components of the irradiation optical system but to directly correct the intensity itself of the line beam having the non-uniformity of the intensity, the specifications regarding alignment of the irradiation optical system, aberration and so forth can be moderated and cost down of the irradiation optical system can be anticipated. Furthermore, since also an influence of the light distribution characteristic of the emitters 11a of the multi-emitter semiconductor laser 11 upon exchange is minimized, the specifications of the multi-emitter semiconductor laser 11 can be moderated and reduction of the running cost of the irradiation optical system can be anticipated.

Now, an irradiation optical system according to a second embodiment of the present invention is described.

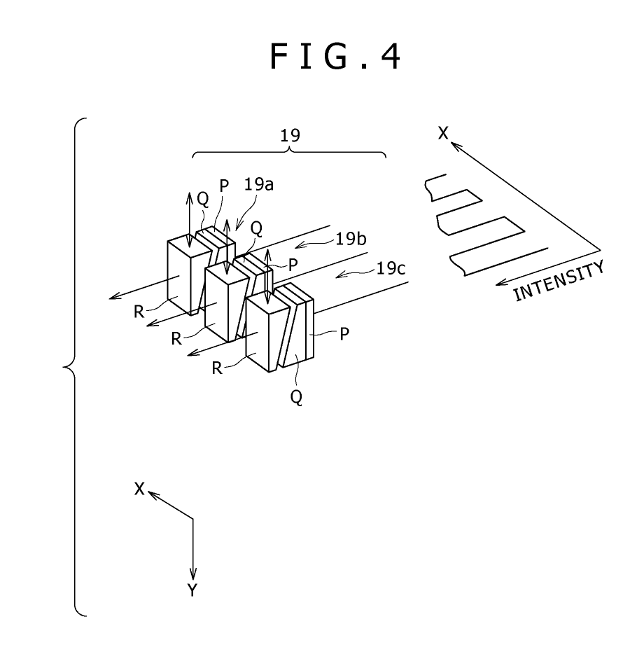

The irradiation optical system of the second embodiment is a modification to but is different from the irradiation optical system of the first embodiment shown in FIGS. 1A and 2A in that it uses such a Soleil compensator as shown in FIG. 4 for the polarization controlling element array 19 of the irradiation optical system shown in FIGS. 1A and 2A. In particular, referring to FIG. 4, each of the polarization controlling elements 19a, 19b and 19c is formed from a Soleil compensator and configured such that a birefringent substrate P having an optical axis in the X-axis direction and a wedge substrate Q having an optical axis in the Y-axis direction are joined together or disposed adjacent each other while a wedge substrate R having an optical axis in the Y-axis direction is disposed so as to face to the wedge substrate Q being capable of being adjusted in the Y-axis direction by sliding by a driving mechanism not shown. By slidably adjusting the wedge substrates R of the polarization controlling elements 19a, 19b and 19c individually in the Y-axis direction, the polarization of luminous fluxes transmitted through the polarization controlling elements 19a, 19b and 19c can be controlled individually. Here, the relationship among the birefringent substrates P, wedge substrates Q, wedge substrates R and the X and Y axes may be reversed to that described above.

The irradiation optical system of the second embodiment has advantages similar to those of the irradiation optical system of the first embodiment described hereinabove. In addition, the irradiation optical system of the second embodiment is advantageous in that, since the wedge substrate R is slidably adjusted, the driving mechanism for the wedge substrate R can be reduced in size. Consequently, the polarization controlling element array 19 can be reduced in size, and as a result, the irradiation optical system can be reduced in size.

Now, an irradiation optical system according to a third embodiment of the present invention is described.

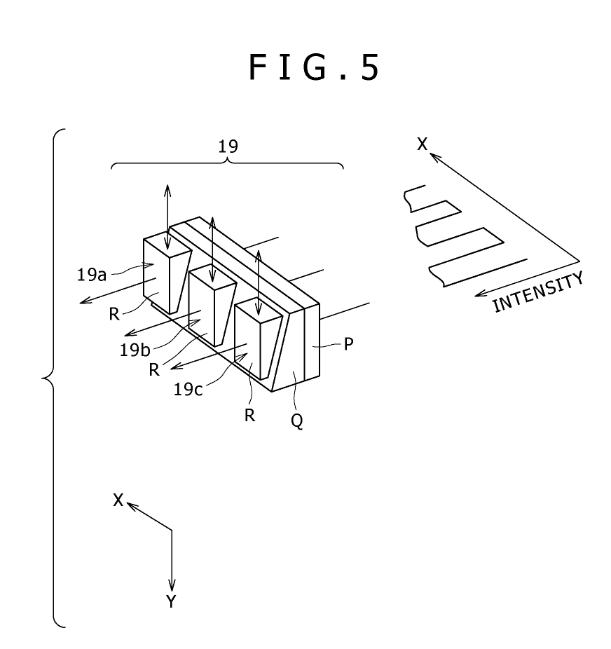

The irradiation optical system of the present embodiment is a modification to but is different from the irradiation optical systems of the first and second embodiments described hereinabove with reference to FIGS. 1A, 2A and 4 in that it uses such a Soleil compensator as shown in FIG. 5 for the polarization controlling element array 19. In particular, referring to FIG. 5, each of the polarization controlling elements 19a, 19b and 19c is formed from a Soleil compensator and configured such that the birefringent substrates P and the wedge substrates Q in the polarization controlling element array 19 of the irradiation optical system of FIG. 4 are formed as a unitary birefringent substrate P and a unitary wedge substrate Q, respectively, which are common to the polarization controlling elements 19a, 19b and 19c. The wedge substrates R provided individually on the polarization controlling elements 19a, 19b and 19c can be slidably adjusted in the Y-axis direction by an individual mechanism not shown.

The irradiation optical system of the third embodiment has advantages similar to those of the irradiation optical system of the first embodiment described hereinabove. In addition, the irradiation optical system of the third embodiment is advantageous in that, since the birefringent substrates P and the wedge substrates Q of the polarization controlling elements 19a, 19b and 19c are formed individually as a unitary member, the number of parts of the polarization controlling element array 19 can be reduced.

Now, an irradiation optical system according to a fourth embodiment of the present invention is described.

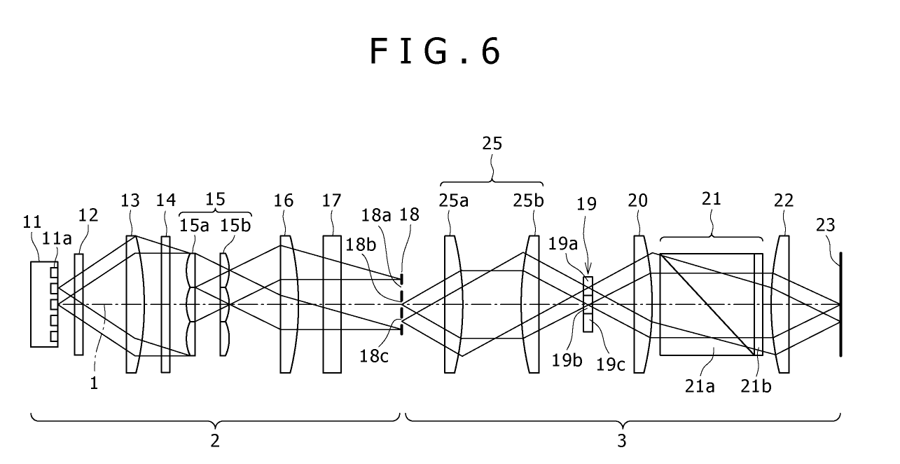

The irradiation optical system of the present embodiment is a modification to but is different from the irradiation optical system of the first embodiment shown in FIGS. 1A and 2A in the position at which the polarization controlling element array 19 is disposed. In particular, referring to FIG. 6 which shows the irradiation optical system of the present embodiment, a relay lens 25 composed of two lenses 25a and 25b is disposed at the next stage to the slit member 18. The polarization controlling element array 19 is disposed at an optically conjugate position with the slit member 18 with respect to the relay lens 25. The polarization controlling element array 19 and the irradiation target 23 are optically conjugate with each other. In other words, the polarization controlling element array 19 is disposed at an optically conjugate position with the slit member 18 and the irradiation target 23.

The irradiation optical system of the fourth embodiment has following advantages in addition to advantages similar to those of the irradiation optical system of the first embodiment described hereinabove. In particular, since the polarization controlling element array 19 need not be disposed immediately behind the slit member 18, luminous fluxes transmitted through the slits of the slit member 18 can be prevented further readily and with a higher degree of certainty from entering not only the polarization controlling elements provided corresponding to the slits but also the other polarization controlling elements. In other words, each of the luminous fluxes emitted from the relay lens 25 can be introduced only to a corresponding one of the polarization controlling elements. Therefore, control of the polarization of the luminous fluxes by the polarization controlling element array 19 can be carried out with a higher degree of certainty, and as a result, the non-uniformity of the intensity of the line beam to be irradiated upon the irradiation target 23 can be further reduced.

Now, an irradiation apparatus according to a fifth embodiment of the present invention is described.

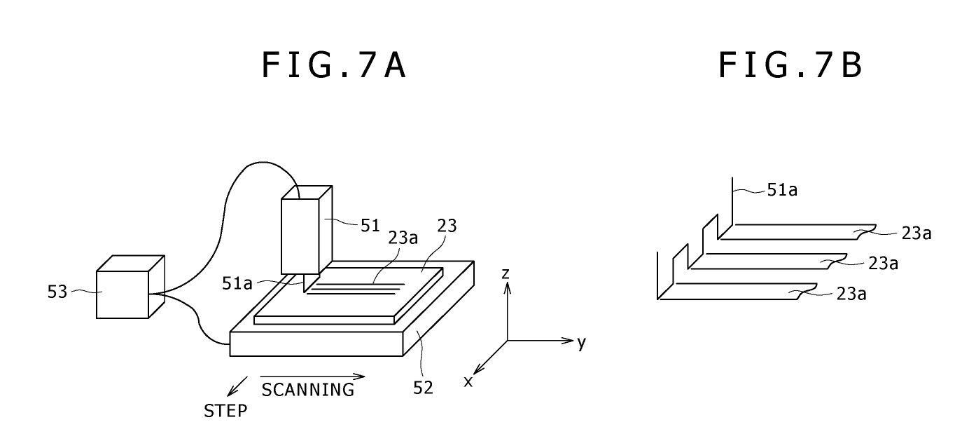

Referring to FIG. 7A, the irradiation apparatus includes an irradiation optical system 51. Any one of the irradiation optical systems of the first to fourth embodiments described hereinabove may be used as the irradiation optical system 51. The irradiation optical system 51 emits a comb-shaped line beam 51a having such a uniform intensity distribution as seen in FIG. 1B. The line beam 51a is shown in an enlarged form in FIG. 7B. A stage 52 is provided below the irradiation optical system 51 for movement in an x-axis direction and a y-axis direction which are perpendicular to each other. The stage 52 can be scanned in the y-axis direction by a control apparatus 53. Further, the stage 52 can be moved step by step in the x-axis direction by the control apparatus 53. The irradiation target 23 is carried on the stage 52.

In the irradiation apparatus, for example, while the stage 52 is scanned in the y-axis direction, the line beam 51a emitted from the irradiation optical system 51 is irradiated upon the irradiation target 23. Then, when the scanning ends, the stage 52 is moved by one step in the axial direction, whereafter the line beam 51a is irradiated on the irradiation target 23 while the stage 52 is scanned in the y-axis direction again. The irradiation area is denoted by reference character 23a. The scanning and the step movement are repeated to carry out irradiation of the line beam 51a over the overall face of the irradiation target 23.

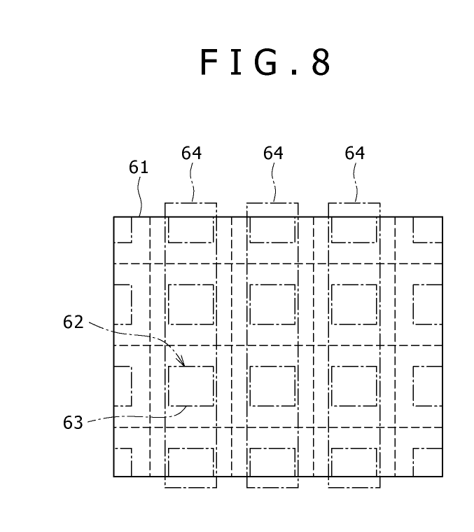

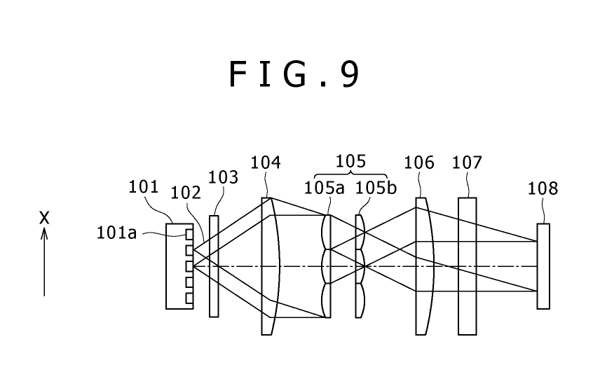

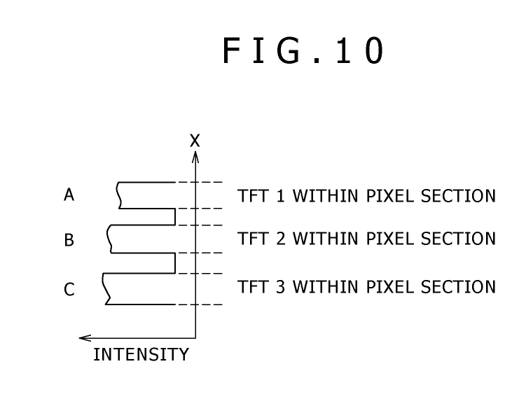

As an example, an application of the irradiation apparatus to fabrication of a TFT substrate of a liquid crystal display or an organic EL display is described. It is assumed that the irradiation target 23 is a glass substrate or the like having an amorphous silicon film for TFT formation formed on an overall face thereof. Referring to FIG. 8, the amorphous silicon film is denoted by reference numeral 61. Pixels 62 and TFT formation regions 63 are shown in FIG. 8. The line beam 51a emitted from the irradiation optical system 51 is irradiated on the amorphous silicon film 61 in a similar manner as described hereinabove with reference to FIGS. 7A and 7B. The line beam 51a is irradiated on the stripes-shaped irradiation regions 64. The amorphous silicon film 61 in the irradiation regions 64 upon which the line beam 51a is irradiated is laser annealed to form a polycrystalline silicon film. Thereafter, for example, the polycrystalline silicon film is patterned into the shape of the TFT formation regions 63, and a gate insulation film is formed over the overall area, whereafter gate electrodes are formed on the gate insulating film. Then, ions of, for example, an n-type impurity are implanted using the gate electrodes as a mask to form source regions and drain regions to form n-channel polycrystalline silicon TFTs.

With the irradiation apparatus according to the fifth embodiment of the present invention, the irradiation intensity among a plurality of stripe-shaped irradiation regions 64 including the TFT formation regions 63 of the amorphous silicon film 61 can be uniformized, and consequently, the amorphous silicon film 61 in the irradiation regions 64 can be laser annealed uniformly. As a result, the characteristic of the n-channel polycrystalline silicon TFT can be uniformized among the pixels.

While the present invention is described in detail in connection with preferred embodiments thereof, the present invention is not limited to the embodiments described above but can be carried out in various modified forms based on the technical scope of the present invention.

For example, the numerical values, structures, configurations, shapes, materials and so forth described above specifically in connection with the embodiments are mere examples at all, and a numerical value, a structure, a configuration, a shape, a material and so forth different from those may be used as occasion demands.

What is claimed is:

1. An irradiation optical system, comprising:
a first projection optical system for mixing a plurality of luminous fluxes outputted from a laser light source having a plurality of linearly arrayed light emitting points with each other and dividing the mixed luminous fluxes into a plurality of luminous fluxes and then projecting, to a slit member having a plurality of slits parallel to each other, the plural luminous fluxes as a line beam extending across the plural slits; and
a second projection optical system for projecting an image of the plural slits of said slit member to an irradiation target,
said second projection optical system including
a polarization controlling element array having a plurality of polarization controlling elements equal to the number of the plural slits, for receiving the plural luminous fluxes transmitted through the plural slits of said slit member and controlling polarization of the received plural luminous fluxes, and
an intensity adjustment element for receiving the plural luminous fluxes transmitted through the polarization controlling element array and adjusting the intensity of the plural luminous fluxes.

2. The irradiation optical system according to claim 1, wherein the distance between the plural polarization controlling elements of said polarization controlling element array is equal to that between the plural slits of said slit member.

3. The irradiation optical system according to claim 2, wherein said laser light source is a multi-emitter semiconductor laser.

4. The irradiation optical system according to claim 3, wherein said polarization controlling element array is disposed adjacent to the slit member in an irradiation target side.

5. The irradiation optical system according to claim 3, wherein said polarization controlling element array is disposed at a position optically conjugate with said slit member and the irradiation target.

6. The irradiation optical system according to claim 5, wherein said second projection optical system projects the image of the plural slits of said slit member to said polarization controlling element array and projects an image obtained by said polarization controlling element array to the irradiation target.

7. The irradiation optical system according to claim 1, wherein each of said polarization controlling elements is formed from a half-wave plate mounted for rotation around a center axis thereof.

8. The irradiation optical system according to claim 1, wherein each of said polarization controlling elements is formed from a Soleil compensator.

9. The irradiation optical system according to claim 8, wherein said Soleil compensator includes a birefringent substrate, a first wedge substrate disposed in a connecting or adjacent relationship with said birefringent substrate and extending orthogonally to an optical axis of said birefringent substrate, and a second wedge substrate having a wedge angle and an optical axis same as those of said first wedge substrate and disposed so as to face to said first wedge substrate, one of said first and second wedge substrates being capable of being adjusted in a wedge direction by sliding.

10. The irradiation optical system according to claim 1, wherein the plural luminous fluxes outputted from the laser light source and mixed with each other are transmitted through said polarization controlling elements.

11. The irradiation optical system according to claim 10, wherein each of said polarization controlling elements is a half-wave plate.

12. The irradiation optical system according to claim 1, wherein said intensity adjustment element is an optical isolator.

13. An irradiation apparatus, comprising:
an irradiation optical system including
a first projection optical system for mixing a plurality of luminous fluxes outputted from a laser light source having a plurality of linearly arrayed light emitting points with each other and dividing the mixed luminous fluxes into a plurality of luminous fluxes and then projecting, to a slit member having a plurality of slits parallel to each other, the plural luminous fluxes as a line beam extending across the plural slits, and
a second projection optical system for projecting an image of the plural slits of said slit member to an irradiation target,
said second projection optical system including
a polarization controlling element array having a plurality of polarization controlling elements equal to the number of the plural slits, for receiving the plural luminous fluxes transmitted through the plural slits of said slit member and controlling polarization of the received plural luminous fluxes, and
an intensity adjustment element for receiving the plural luminous fluxes transmitted through the polarization controlling element array and adjusting the intensity of the plural luminous fluxes.

14. A fabrication method for a semiconductor device, comprising a step of:
irradiating, on a semiconductor substrate or a semiconductor film, a line beam obtained using an irradiation apparatus which includes an irradiation optical system which in turn includes
a first projection optical system for mixing a plurality of luminous fluxes outputted from a laser light source having a plurality of linearly arrayed light emitting points with each other and dividing the mixed luminous fluxes into a plurality of luminous fluxes and then projecting, to a slit member having a plurality of slits parallel to each other, the plural luminous fluxes as a line beam extending across the plural slits, and
a second projection optical system for projecting an image of the plural slits of said slit member to an irradiation target,
said second projection optical system including
a polarization controlling element array having a plurality of polarization controlling elements equal to the number of the plural slits, for receiving the plural luminous fluxes transmitted through the plural slits of said slit member and controlling polarization of the received plural luminous fluxes, and
an intensity adjustment element for receiving the plural luminous fluxes transmitted through the polarization controlling element array and adjusting the intensity of the plural luminous fluxes.
